(19) United States
(12) Patent Application Publication
(10) Pub. No.: US 2017/0263478 A1
(43) Pub. Date: Sep. 14, 2017

(54) Detection System for Tunable/Replaceable Edge Coupling Ring

(71) Applicant: LAM RESEARCH CORPORATION, Fremont, CA (US)

(72) Inventors: Jon McCHESNEY, Fremont, CA (US); Yuhou WANG, Fremont, CA (US); Damon Tyrone GENETTI, Livermore, CA (US); Alexander PATERSON, San Jose, CA (US)

(73) Assignee: LAM RESEARCH CORPORATION, Fremont, CA (US)

(21) Appl. No.: 15/609,570

(22) Filed: May 31, 2017

Related U.S. Application Data
(63) Continuation-in-part of application No. 14/705,430, filed on May 6, 2015.
Application No. 14/705,430 is a continuation-in-part of application No. 14/598,943, filed on Jan. 16, 2015.

(51) Int. Cl. H01L 21/67; H01L 21/683; H01J 37/32; H01L 21/687

(52) U.S. Cl. CPC H01L 21/67259; H01L 21/67253; H01L 21/67069; H01L 21/68785; H01L 21/68742; H01L 21/6833; H01L 21/68735; H01J 37/32715; H01J 37/32697; H01J 37/32082; H01J 2237/334; H01J 2237/2007

(57) ABSTRACT

A substrate processing system includes a processing chamber. A pedestal is arranged in the processing chamber. An edge coupling ring is arranged adjacent to the pedestal and around a radially outer edge of the substrate. An actuator is configured to selectively move the edge coupling ring relative to the substrate to alter an edge coupling profile of the edge coupling ring. The substrate processing system includes a camera-based detection system that instructs the actuator to adjust a position of the edge coupling ring. The camera is configured to communicate with the controller, and the controller adjusts a position and/or focus of the camera. In response to edge coupling ring condition information from the camera, the controller operates the actuator to move the edge coupling ring vertically. In response to edge coupling ring position information from the camera, the controller operates the actuator to move the edge coupling ring horizontally.

### CROSS-REFERENCE TO RELATED APPLICATIONS

The present application is a continuation-in-part of U.S. application Ser. No. 14/705,430, filed May 6, 2015. That application in turn is a continuation-in-part of U.S. application Ser. No. 14/598,943, filed Jan. 16, 2015. The present application incorporates both of these prior applications by reference in their entirety.

### FIELD

The present disclosure relates to substrate processing systems, more particularly to edge coupling rings of substrate processing systems, and yet more particularly to detection systems for edge coupling rings of substrate processing systems. Still more particularly, the present disclosure relates to detection systems for detecting a position and/or condition of edge coupling rings of substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform etching and/or other treatment of substrates such as semiconductor wafers. A substrate may be arranged on a pedestal in a processing chamber of the substrate processing system. For example, during etching in a plasma etcher, a gas mixture including one or more precursors is introduced into the processing chamber and plasma is struck to etch the substrate.

Edge coupling rings have been used to adjust an etch rate and/or etch profile of the plasma near a radially outer edge of the substrate. The edge coupling ring is typically located on the pedestal around the radially outer edge of the substrate. Process conditions at the radially outer edge of the substrate can be modified by changing a position of the edge coupling ring, a shape or profile of an inner edge of the edge coupling ring, a height of the edge coupling ring relative to an upper surface of the substrate, a material of the edge coupling ring, etc.

Changing the edge coupling ring requires the processing chamber to be opened, which is undesirable. In other words, an edge coupling effect of the edge coupling ring cannot be altered without opening the processing chamber. When the edge coupling ring is eroded by plasma during etching, the edge coupling effect changes. Correcting erosion of the edge coupling ring requires the processing chamber to be opened in order to replace the edge coupling ring.

Referring now to FIGS. 1-2, a substrate processing system may include a pedestal 20 and an edge coupling ring 30. The edge coupling ring 30 may include a single piece or two or more portions. In the example in FIGS. 1-2, the edge coupling ring 30 includes a first annular portion 32 arranged near a radially outer edge of a substrate 33. A second annular portion 34 is located radially inwardly from the first annular portion below the substrate 33. A third annular portion 36 is arranged below the first annular portion 32. During use, plasma 42 is directed at the substrate 33 to etch the exposed portions of the substrate 33. The edge coupling ring 30 is arranged to help shape the plasma such that uniform etching of the substrate 33 occurs.

In FIG. 2, after the edge coupling ring 30 has been used, an upper surface of a radially inner portion of the edge coupling ring 30 may exhibit erosion as identified at 48. As a result, plasma 42 may tend to etch a radially outer edge of the substrate 33 at a faster rate than etching of radially inner portions thereof as can be seen at 44.

One or more portions of an edge coupling ring may be moved vertically and/or horizontally relative to a substrate or pedestal in a substrate processing system. The movement changes an edge coupling effect of the plasma relative to the substrate during etching or other substrate treatment without requiring the processing chamber to be opened.

Referring now to FIGS. 3-5, a substrate processing system includes a pedestal 20 and an edge coupling ring 60. The edge coupling ring 60 may be made of a single portion or two or more portions may be used. In the example in FIGS. 3-5, the edge coupling ring 60 includes a first annular portion 72 arranged radially outside of the substrate 33. A second annular portion 74 is located radially inwardly from the first annular portion 72 below the substrate 33. A third annular portion 76 is arranged below the first annular portion 72.

An actuator 80 may be arranged in various locations to move one or more portions of the edge coupling ring 60 relative to the substrate 33 as will be described further below. For example only, in FIG. 3 the actuator 80 is arranged between the first annular portion 72 of the edge coupling ring 60 and the third annular portion 76 of the edge coupling ring 60. In some examples, the actuator 80 may include a piezoelectric actuator, a stepper motor, a pneumatic drive, or other suitable actuator. In some examples, one, two, three, or four or more actuators are used. In some examples, multiple actuators are arranged uniformly around the edge coupling ring 60. The actuator(s) 80 may be arranged inside or outside of the processing chamber.

During use, plasma 82 is directed at the substrate 33 to etch the exposed portions of the substrate 33. The edge coupling ring 60 is arranged to help shape the plasma electric field such that uniform etching of the substrate 33 occurs. As can be seen at 84 and 86 in FIG. 4, one or more portions of the edge coupling ring 60 may be eroded by the plasma 82. As a result of the erosion, non-uniform etching of the substrate 33 may occur near a radially outer edge of the substrate 33. Normally, the process would need to be stopped, the processing chamber opened and the edge coupling ring replaced.

In FIG. 5, the actuator 80 is used to move one or more portions of the edge coupling ring 60 to alter the position of the one or more portions of the edge coupling ring 60. For example, the actuator 80 may be used to move the first annular portion 72 of the edge coupling ring 60. In this example, the actuator 80 moves the first annular portion 72 of the edge coupling ring 60 in an upward or vertical direction such that an edge 86 of the first annular portion 72 of the edge coupling ring 60 is higher relative to the radially outer edge of the substrate 33. As a result, etch uniformity near the radially outer edge of the substrate 33 is improved.

Referring now to FIG. 6, as can be appreciated, the actuator may be arranged in one or more other locations and may move in other directions such as horizontal, diagonal, etc. Horizontal movement of the portion of the edge coupling ring may be performed to center the edge coupling effect relative to the substrate. In FIG. 6, an actuator 110 is arranged radially outside of the edge coupling ring 60. In addition, the actuator 110 moves in a vertical (or an up/down) direction as well as in a horizontal (or side to side) direction. Horizontal repositioning may be used when etching of the substrates shows a horizontal offset of the edge coupling ring relative to the substrates. The horizontal offset may be corrected without opening the processing chamber. Likewise, tilting of the edge coupling ring may be performed by actuating some of the actuators differently than others of the actuators to correct or create side-to-side asymmetry.

Rather than locating the actuator 110 between annular portions of the edge coupling ring, the actuator 110 may also be attached to a radially outer wall or other structure identified at 114. Alternately, the actuator 110 may be supported from below by a wall or other structure identified at 116.

Referring now to FIG. 7-8, another example of an edge coupling ring 150 and a piezoelectric actuator 154 is shown. In this example, the piezoelectric actuator 154 moves the edge coupling ring 150. The piezoelectric actuator 154 is mounted in the first annular portion 72 and the third annular portion 76 of the edge coupling ring 60. In FIG. 8, the piezoelectric actuator 154 moves the first annular portion 72 of the edge coupling ring 150 to adjust a position of an edge 156 of the first annular portion 72.

Keeping the processing chamber closed can present difficulties in observing the condition of the edge coupling ring, and consequently in determining when to adjust the ring's position to compensate for erosion and when to replace the ring.

In addition, when replacing an edge coupling ring, there can be difficulties in positioning and/or aligning the edge coupling ring appropriately.

### SUMMARY

A substrate processing system includes a processing chamber. The processing chamber has a covered opening through which conditions in the chamber can be observed and/or measured, including the condition and/or position of an edge coupling ring that is arranged adjacent to a pedestal in the processing chamber and around a radially outer edge of the substrate. A detection system that detects the condition and/or position of the edge coupling ring is provided.

In one feature, the detection system includes a camera with optics suitable to permit observation of the condition of the edge coupling ring without opening the processing chamber.

In one feature, the apparatus includes a laser inferometer to measure the profile of the edge coupling ring without opening the processing chamber.

Depending on the observed condition and/or measurement, for example, in response to erosion of a plasma-facing surface of the edge coupling ring, an actuator is configured to selectively move a first portion of the edge coupling ring relative to the substrate to alter an edge coupling profile of the edge coupling ring, without requiring the processing chamber to be opened.

In other features, the actuator is configured to move the first portion of the edge coupling ring relative to a second portion of the edge coupling ring.

In other features, a controller is configured to move the edge coupling ring in response to erosion of a plasma-facing surface of the edge coupling ring. The controller automatically moves the edge coupling ring after the edge coupling ring is exposed to a predetermined number of etching cycles. The controller automatically moves the edge coupling ring after the edge coupling ring is exposed to a predetermined period of etching.

In other features, the actuator moves the first portion of the edge coupling ring vertically relative to the substrate. The actuator moves the first portion of the edge coupling ring horizontally relative to the substrate. A sensor or detector is configured to communicate with the controller and to detect the erosion of the edge coupling ring.

In other features, the detector is a camera mounted outside the processing chamber, and sighted on the edge coupling ring through a side view port of the chamber.

In other features, the camera may provide images or other information of the condition and/or position of the edge coupling ring using plasma lighting, or using external lighting. In other features, the external lighting may be provided through the same side view port through which the camera is sighted, or may be provided through a different side view port.

In other features, the detection system includes a controller that adjusts a position and/or focus of the camera. In other features, the controller that moves the actuator also adjusts the position and/or focus of the camera. The camera is configured to communicate with the controller, and the controller adjusts a position and/or focus of the camera. In response to edge coupling ring condition information from the camera, the controller operates the actuator to adjust a position of the edge coupling ring relative to the substrate. In response to edge coupling ring condition information from the camera, the controller operates the actuator to move the edge coupling ring vertically. In response to edge coupling ring position information from the camera, the controller operates the actuator to move the edge coupling ring horizontally. In response to edge coupling ring orientation information from the camera, the controller operates the actuator to move one side of the edge coupling ring relative to another side.

In other features, the robot is configured to communicate with the controller and to adjust a position of the sensor. The sensor includes a depth gauge. The sensor includes a laser interferometer. The actuator selectively tilts the edge coupling ring relative to the substrate. The actuator is located outside of the processing chamber. A rod member connects the actuator to the edge coupling ring through a wall of the processing chamber.

In other features, a seal is arranged between the rod member and the wall of the processing chamber. A controller is configured to move the edge coupling ring to a first position for a first treatment of the substrate using a first edge coupling effect and then to a second position for a second treatment of the substrate using a second edge coupling effect.

A method for adjusting an edge coupling profile of an edge coupling ring in a substrate processing system includes arranging an edge coupling ring adjacent to a pedestal in a processing chamber. The edge coupling ring is arranged around a radially outer edge of the substrate. The method includes selectively moving a first portion of the edge coupling ring relative to the substrate using an actuator to alter an edge coupling profile of the edge coupling ring.

In other features, the method includes delivering process gas and carrier gas to the processing chamber. The method includes creating plasma in the processing chamber to etch the substrate. The method includes moving the first portion of the edge coupling ring using the actuator without requiring the processing chamber to be opened. The edge coupling ring further comprises a second portion. The actuator is configured to move the first portion of the edge coupling ring relative the second portion of the edge coupling ring. The actuator is selected from a group consisting of a piezoelectric actuator, a stepper motor actuator, and a pneumatic drive actuator.

In other features, the method includes moving the edge coupling ring in response to erosion of a plasma-facing surface of the edge coupling ring. The method includes automatically moving the edge coupling ring after the edge coupling ring is exposed to a predetermined number of etching cycles. The method includes automatically moving the edge coupling ring after the edge coupling ring is exposed to a predetermined period of etching. The method includes moving the first portion of the edge coupling ring vertically relative to the substrate. The method includes moving the first portion of the edge coupling ring horizontally relative to the substrate.

In other features, the method includes moving the first portion of the edge coupling ring vertically relative to the substrate. The method includes moving the first portion of the edge coupling ring horizontally relative to the substrate. A sensor or detector is configured to communicate with the controller and to detect the erosion of the edge coupling ring.

In other features, the method includes using a camera to sense erosion of the edge coupling ring. The method includes adjusting a position of the edge coupling ring using images from the camera. The method includes operating the actuator to adjust a position of the edge coupling ring relative to the substrate in response to position information that the camera provides. The method includes operating the actuator to move the edge coupling ring vertically in response to information that the camera provides regarding a condition of the edge coupling ring. The method includes operating the actuator to move the edge coupling ring horizontally in response to information that the camera provides regarding a position of the edge coupling ring. The method includes operating the actuator to move one side of the edge coupling ring relative to another side in response to information that the camera provides regarding a position of the edge coupling ring.

In other features, the method includes using a sensor to sense erosion of the edge coupling ring. The sensor is selected from a group consisting of a depth gauge and a laser interferometer. The method includes selectively tilting the edge coupling ring relative to the substrate. The actuator is located outside of the processing chamber.

In other features, the method includes moving the edge coupling ring to a first position for a first treatment of the substrate using a first edge coupling effect and moving the edge coupling ring to a second position for a second treatment of the substrate using a second edge coupling effect.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of a pedestal and an edge coupling ring according to the prior art;

FIG. 2 is a side cross-sectional view of a pedestal and an edge coupling ring according to the prior art after erosion of the edge coupling ring has occurred;

FIG. 3 is a side cross-sectional view of an example of a pedestal, an edge coupling ring and an actuator;

FIG. 4 is a side cross-sectional view of the pedestal, the edge coupling ring and the actuator of FIG. 3 after erosion of the edge coupling ring has occurred;

FIG. 5 is a side cross-sectional view of the pedestal, the edge coupling ring and the actuator of FIG. 3 after erosion of the edge coupling ring has occurred and the actuator is moved;

FIG. 6 is a side cross-sectional view of another example of a pedestal, an edge coupling ring and an actuator located in another position according to the present disclosure;

FIG. 7 is a side cross-sectional view of another example of a pedestal, an edge coupling ring and a piezoelectric actuator according to the present disclosure;

FIG. 8 is a side cross-sectional view of the pedestal, the edge coupling ring and the piezoelectric actuator of FIG. 7 after erosion has occurred and the piezoelectric actuator is moved;

FIG. 9 is a functional block diagram of an example of a substrate processing chamber including a pedestal, an edge coupling ring and an actuator according to the present disclosure;

FIG. 10 is a flowchart illustrating steps of an example of a method for operating the actuator to move the edge coupling ring according to the present disclosure;

FIG. 11 is a flowchart illustrating steps of another example of a method for operating the actuator to move the edge coupling ring according to the present disclosure;

FIG. 12 is a functional block diagram of an example of a processing chamber including an edge coupling ring movable by actuators arranged outside of the processing chamber according to the present disclosure;

FIGS. 13A and 13B illustrates an example of side-to-side tilting of an edge coupling ring according to the present disclosure; and

FIG. 14 illustrates an example of a method for moving an edge coupling ring during processing of a substrate.

FIG. 15 is a plan view of an example of a pedestal including an edge coupling ring and a lifting ring;

FIG. 16 is a side cross-sectional view of an example of the edge coupling ring and lifting ring;

FIG. 17 is a side cross-sectional view of an example of the edge coupling ring being lifted by the lifting ring and the edge coupling ring being removed by a robot arm;

FIG. 18 is a side cross-sectional view of an example of a movable edge coupling ring and a lifting ring;

FIG. 19 is a side cross-sectional view of the movable edge coupling ring of FIG. 18 in a raised position;

FIG. 20 is a side cross-sectional view of the edge coupling ring of FIG. 18 being lifted by the lifting ring and the edge coupling ring being removed by a robot arm;

FIG. 21 is a side cross-sectional view of an example of a movable edge coupling ring;

FIG. 22 is a side cross-sectional view of the edge coupling ring of FIG. 21 being lifted by the actuator and removed by a robot arm;

FIG. 23 is an example of a method for replacing an edge coupling ring without opening a processing chamber;

FIG. 24 is an example of a method for moving an edge coupling ring due to erosion and replacing an edge coupling ring without opening a processing chamber;

FIG. 25 is an example of a method for raising an edge coupling ring due to erosion and replacing the edge coupling ring without opening a processing chamber;

FIG. 26 is a side cross-sectional view of a processing chamber with an example of a detector mounted outside the chamber;

FIG. 27 is a side cross-sectional view of a processing chamber with an example of a detector and lighting device mounted outside the chamber;

FIG. 28 is a side cross-sectional view of a processing chamber with the edge coupling ring in an etched or eroded state;

FIG. 29A shows an enlarged side view of a liner, and FIGS. 29B and 29C show examples of good and bad edge coupling ring placement relative to the liner;

FIGS. 30A-30C show examples of images with different positions and states of the edge coupling ring;

FIG. 31 is a side cross-sectional view showing an alternative mode of imaging of the edge coupling ring using the detector;

FIG. 32 is an example of a method for examining an edge coupling ring to determine its alignment on an electrostatic chuck;

FIG. 33 is an example of a method for examining an edge coupling ring to determine its condition.

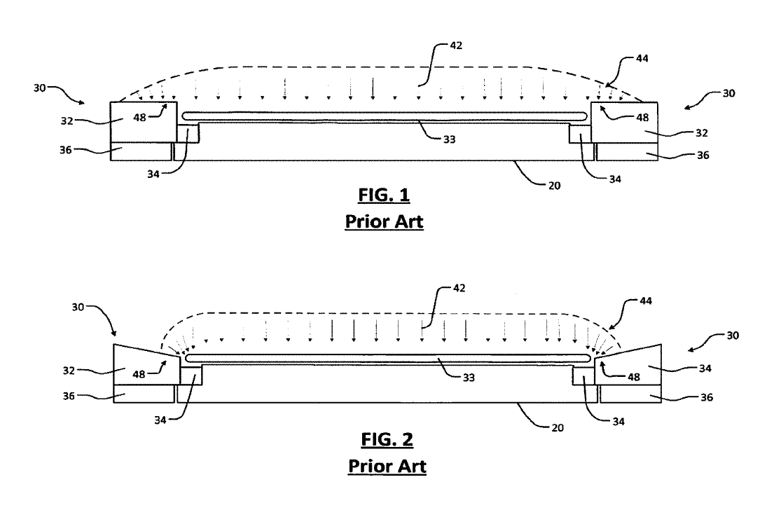

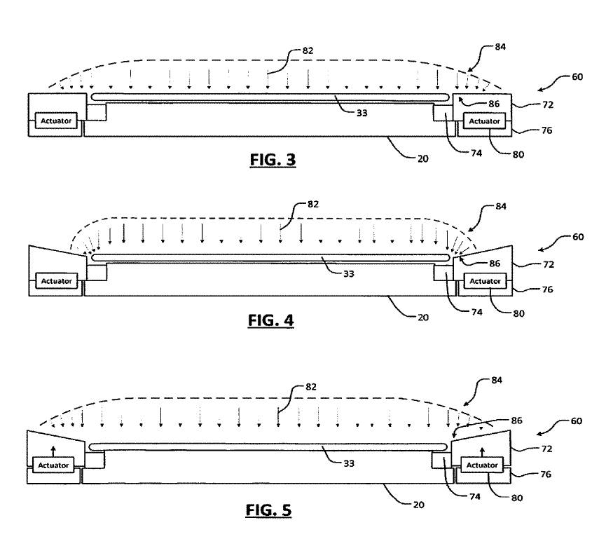

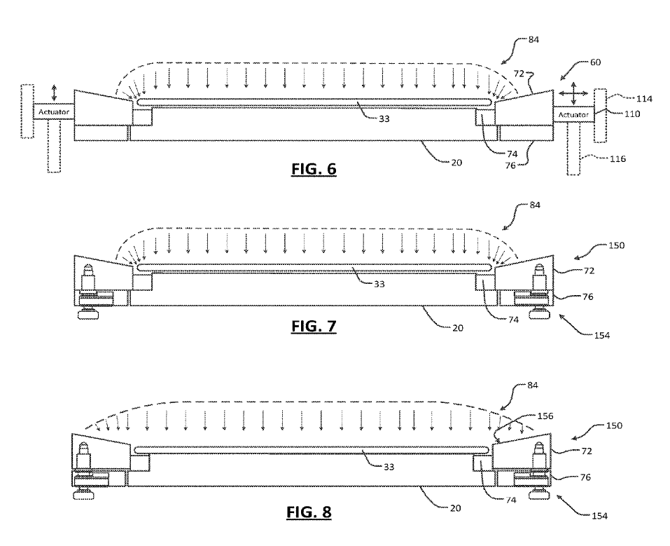

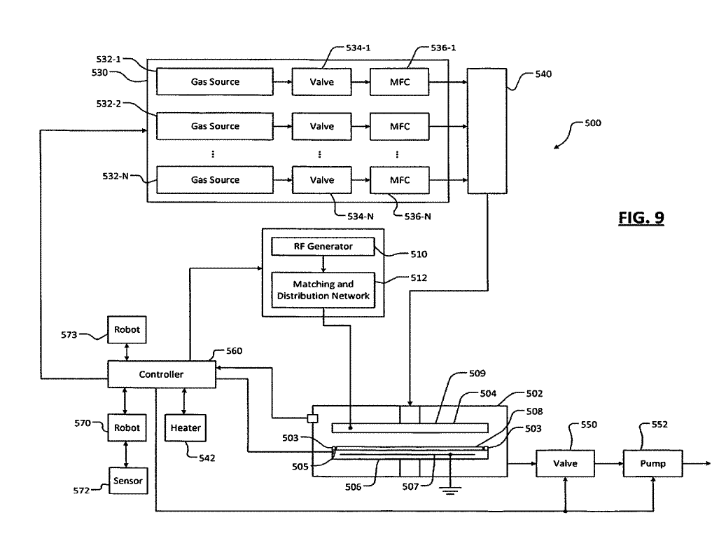

In the drawings, reference numbers may be reused to identify similar and/or identical elements.

### DETAILED DESCRIPTION

Referring now to FIG. 9, an example of a substrate processing chamber 500 for performing etching using RF plasma is shown. The substrate processing chamber 500 includes a processing chamber 502 that encloses other components of the substrate processing chamber 500 and contains the RF plasma. The substrate processing chamber 500 includes an upper electrode 504 and a pedestal 506 including a lower electrode 507. An edge coupling ring 503 is supported by the pedestal 506 and is arranged around the substrate 508. One or more actuators 505 may be used to move the edge coupling ring 503. During operation, a substrate 508 is arranged on the pedestal 506 between the upper electrode 504 and the lower electrode 507.

For example only, the upper electrode 504 may include a showerhead 509 that introduces and distributes process gases. The showerhead 509 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 504 may include a conducting plate and the process gases may be introduced in another manner. The lower electrode 507 may be arranged in a non-conductive pedestal. Alternately, the pedestal 506 may include an electrostatic chuck that includes a conductive plate that acts as the lower electrode 507.

An RF generating system 510 generates and outputs an RF voltage to one of the upper electrode 504 and the lower electrode 507. The other one of the upper electrode 504 and the lower electrode 507 may be DC grounded, AC grounded or floating. For example only, the RF generating system 510 may include an RF voltage generator 511 that generates the RF voltage that is fed by a matching and distribution network 512 to the upper electrode 504 or the lower electrode 507. In other examples, the plasma may be generated inductively or remotely.

A gas delivery system 530 includes one or more gas sources 532-1, 532-2, . . . , and 532-N (collectively gas sources 532), where N is an integer greater than zero. The gas sources supply one or more precursors and mixtures thereof. The gas sources may also supply purge gas. Vaporized precursor may also be used. The gas sources 532 are connected by valves 534-1, 534-2, . . . , and 534-N (collectively valves 534) and mass flow controllers 536-1, 536-2, . . . , and 536-N (collectively mass flow controllers 536) to a manifold 540. An output of the manifold 540 is fed to the processing chamber 502. For example only, the output of the manifold 540 is fed to the showerhead 509.

A heater 542 may be connected to a heater coil (not shown) arranged in the pedestal 506. The heater 542 may be used to control a temperature of the pedestal 506 and the substrate 508. A valve 550 and pump 552 may be used to evacuate reactants from the processing chamber 502. A controller 560 may be used to control components of the substrate processing chamber 500. The controller 560 may also be used to control the actuator 505 to adjust a position of one or more portions of the edge coupling ring 503.

A robot 570 and a sensor 572 may be used to measure erosion of the edge coupling ring. In some examples, the sensor 572 may include a depth gauge. The robot 570 may move the depth gauge in contact with the edge coupling ring to measure erosion. Alternately, a laser interferometer (with or without the robot 570) may be used to measure erosion without direct contact. The robot 570 may be omitted if the laser interferometer can be positioned with a direct line of sight to the edge coupling ring.

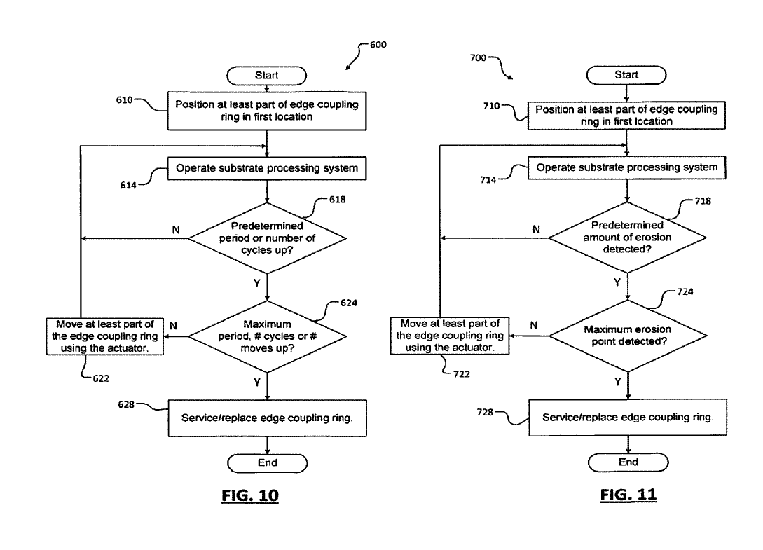

Referring now to FIG. 10, an example of a method 600 for operating the actuator to move the edge coupling ring is shown. At 610, at least part of an edge coupling ring is positioned in a first location relative to the substrate. At 614, the substrate processing system is operated. The operation may include etching or other treatment of a substrate. At 618, control determines whether a predetermined period of etching or a predetermined number etching cycles have occurred. If the predetermined period or number of cycles is not exceeded as determined at 618, control returns to 614.

When the predetermined period or number of cycles are up, control determines at 624 whether a maximum predetermined etching period is up, a maximum number of etching cycles has occurred and/or a maximum # of actuator moves have occurred.

If 624 is false, control moves at least part of the edge coupling ring using the actuator. Movement of the edge coupling ring can be performed automatically, manually or a combination thereof without opening the processing chamber. If 624 is true, control sends a message or otherwise indicates that the edge coupling ring should be serviced/replaced.

Referring now to FIG. 11, an example of a method 700 for operating the actuator to move the edge coupling ring is shown. At 710, at least part of an edge coupling ring is positioned in a first location relative to the substrate. At 714, the substrate processing system is operated. The operation may include etching or other treatment of a substrate. At 718, control determines whether a predetermined amount of erosion of the edge coupling ring has occurred using a sensor such as a depth gauge or laser interferometer. If 718 is false, control returns to 714.

When the predetermined amount of erosion has occurred, control determines at 724 whether a maximum amount of erosion has occurred. If 724 is false, control moves at least part of the edge coupling ring using the actuator. Movement of the edge coupling ring can be performed automatically, manually or a combination thereof without opening the processing chamber. If 724 is true, control sends a message or otherwise indicates that the edge coupling ring should be serviced/replaced.

In addition to the foregoing, a determination of whether or not the edge coupling ring needs to be moved may be based on inspection of etching patterns of the substrates after processing. The actuator may be used to adjust the edge coupling profile of the edge coupling ring without opening the chamber.

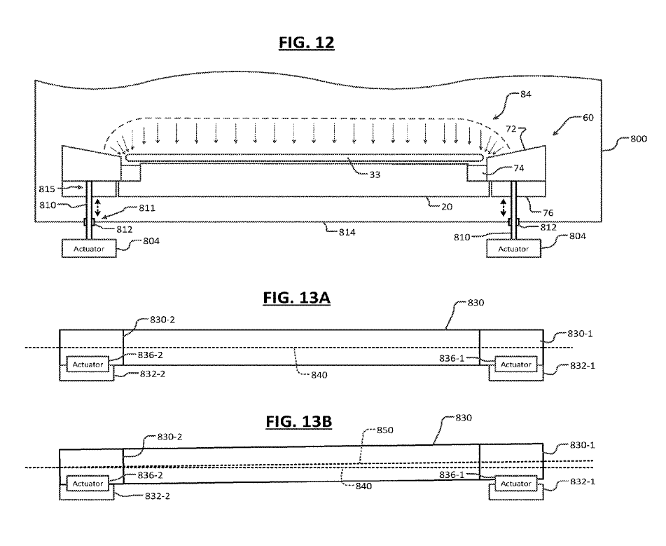

Referring now to FIG. 12, a processing chamber 800 includes an edge coupling ring 60 arranged on a pedestal 20. The edge coupling ring 60 includes one or more portions that are movable by one or more actuators 804 arranged outside of the processing chamber 800. In this example, the portion 72 is movable. The actuators 804 may be connected by mechanical linkage 810 to the portion 72 of the edge coupling ring 60. For example, the mechanical linkage 810 may include a rod member. The mechanical linkage 810 may pass through a hole 811 in a wall 814 of the processing chamber 800. A seal 812 such as an “O”-ring may be used. The mechanical linkage 810 may pass through holes 815 in one or more structures such as the portion 76 of the edge coupling ring 60.

Referring now to FIGS. 13A and 13B, side-to-side tilting of an edge coupling ring 830 is shown. Side-to-side tilting may be used to correct side-to-side misalignment. In FIG. 13A, portions 830-1 and 830-2 of an edge coupling ring 830 on opposite sides of the substrate are arranged in a first arrangement 840. The portions 830-1 and 830-2 may be generally aligned with portions 832-1 and 832-2 of the edge coupling ring 830. Actuators 836-1 and 836-2 are arranged between the portions 830-1 and 832-1 and 830-2 and 832-2, respectively.

In FIG. 13B, the actuators 836-1 and 836-2 move the respective portions of the edge coupling ring 830 such that the edge coupling ring 830 moves to a second arrangement 850 that is different than the first arrangement 840 shown in FIG. 13A. As can be appreciated, the substrates may be inspected after treatment and the tilt relative to the substrate may be adjusted as needed without opening the processing chamber.

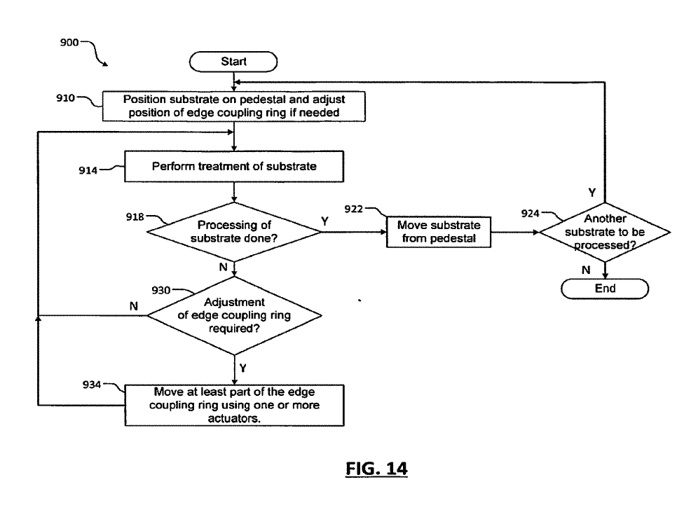

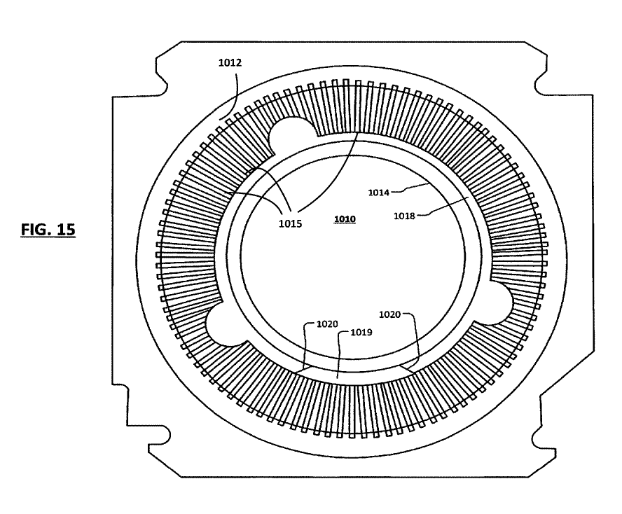

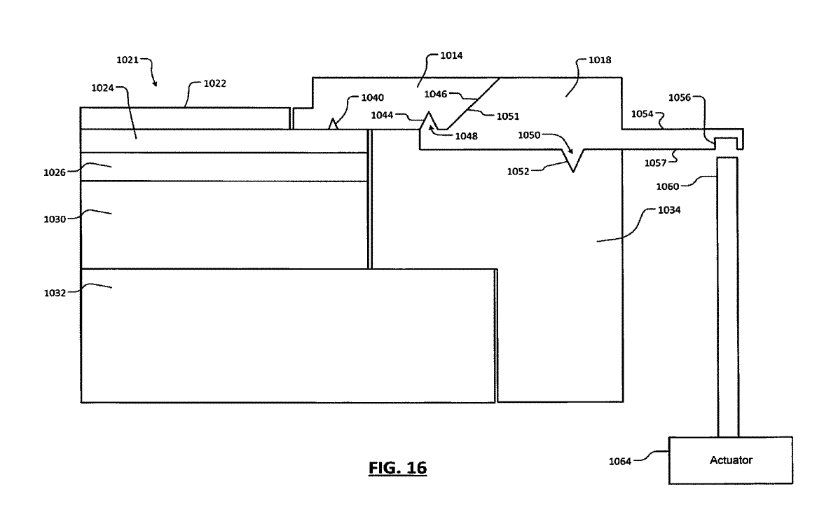

Referring now to FIG. 14, a method 900 for moving an edge coupling ring during processing of a substrate is shown. In other words, different treatments may be performed on a single substrate in the same processing chamber. The edge coupling effect of the edge coupling ring may be adjusted between the multiple treatments performed on the substrate in the same processing chamber before proceeding to a subsequent substrate. At 910, a substrate is positioned on a pedestal and a position of the edge coupling ring is adjusted if needed. At 914, treatment of the substrate is performed. If processing of the substrate is done as determined at 918, the substrate is moved from the pedestal at 922. At 924, control determines whether another substrate needs to be processed. If 924 is true, the method returns to 910. Otherwise the method ends.

If 918 is false and the substrate needs additional treatment, the method determines whether adjustment of the edge coupling ring is required at 930. If 930 is false, the method returns to 914. If 930 is true, at least part of the edge coupling ring is moved using one or more actuators at 934 and the method returns to 914. As can be appreciated, the edge coupling ring can be adjusted between treatments of the same substrate in the same processing chamber.

Referring now to FIG. 15, an edge coupling ring 1014 and a lifting ring 1018 are arranged adjacent to and around an upper surface of a pedestal 1010. The edge coupling ring 1014 includes a radially inner edge that is arranged adjacent to the substrate during etching as described above. The lifting ring 1018 is arranged below at least part of the edge coupling ring 1014. The lifting ring 1018 is used to raise the edge coupling ring 1014 above a surface of the pedestal 1010 when removing the edge coupling ring 1014 using a robot arm. The edge coupling ring 1014 can be removed without requiring the processing chamber to be opened to atmospheric pressure. In some examples, the lifting ring 1018 may optionally include an open portion 1019 between circumferentially spaced ends 1020 to provide clearance for a robot arm to remove the edge coupling ring 1014 as will be described below.

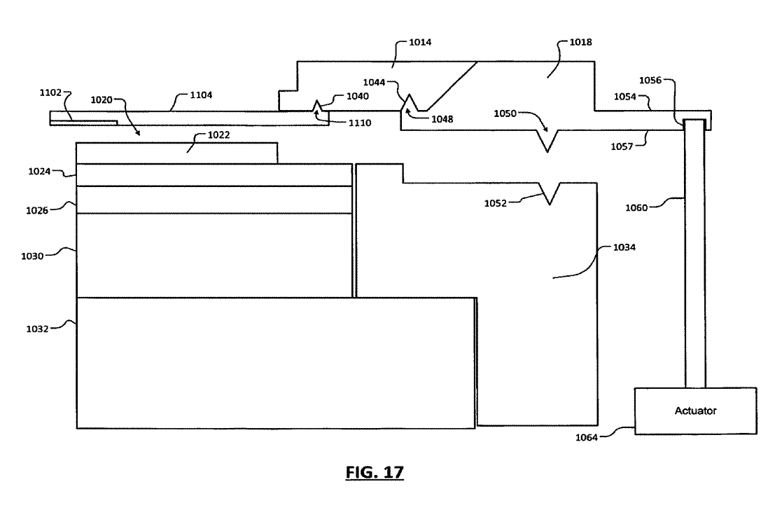

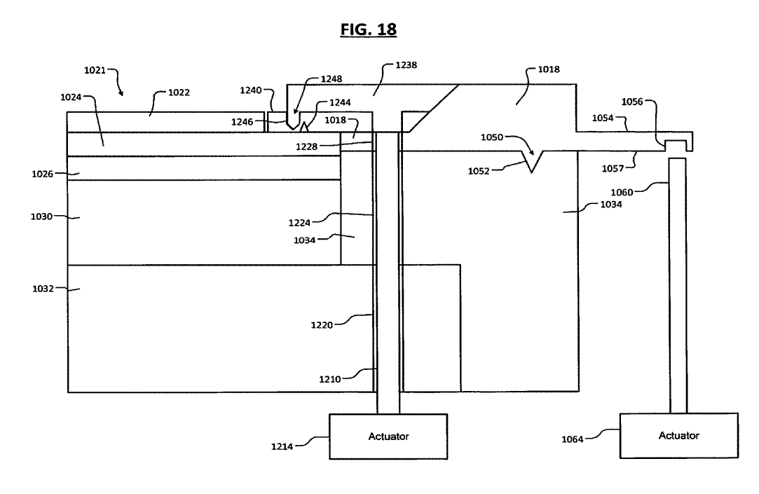

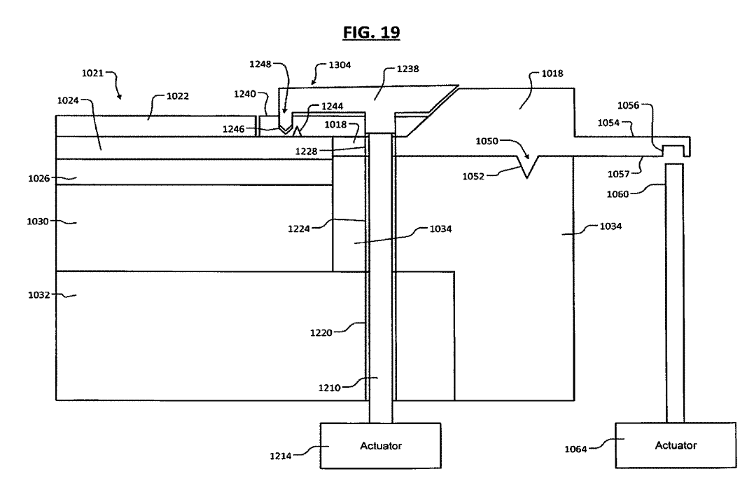

Referring now to FIGS. 16-17, an example of the edge coupling ring 1014 and lifting ring 1018 are shown in further detail. In the example shown in FIG. 16, the pedestal may include an electrostatic chuck (ESC) generally identified at 1021. The ESC 1021 may include one or more stacked plates such as ESC plates 1022, 1024, 1030 and 1032. The ESC plate 1030 may correspond to a middle ESC plate and the ESC plate 1032 may correspond to an ESC baseplate. In some examples, an O-ring 1026 may be arranged between the ESC plates 1024 and 1030. While a specific pedestal 1010 is shown, other types of pedestals may be used.

A bottom edge coupling ring 1034 may be arranged below the edge coupling ring 1014 and the lifting ring 1018. The bottom edge coupling ring 1034 may be arranged adjacent to and radially outside of the ESC plates 1024, 1030 and 1032 and the O-ring 1026.

In some examples, the edge coupling ring 1014 may include one or more self-centering features 1040, 1044 and 1046. For example only, the self-centering features 1040 and 1044 may be triangular-shaped, female self-centering features, although other shapes may be used. The self-centering feature 1046 may be a sloped surface. The lifting ring 1018 may include one or more self-centering features 1048, 1050 and 1051. For example only, the self-centering features 1048 and 1050 may be triangular-shaped, male self-centering features, although other shapes may be used. The self-centering feature 1051 may be a sloped surface having a complementary shape to the self-centering feature 1046. The self-centering feature 1048 on the lifting ring 1018 may mate with the self-centering feature 1044 on the edge coupling ring 1014. The self-centering feature 1050 on the lifting ring 1018 may mate with a self-centering feature 1052 of the bottom edge coupling ring 1034.

The lifting ring 1018 further includes a projection 1054 that extends radially outwardly. A groove 1056 may be arranged on a bottom-facing surface 1057 of the projection 1054. The groove 1056 is configured to be biased by one end of a pillar 1060 that is connected to and selectively moved vertically by an actuator 1064. The actuator 1064 may be controlled by the controller. As can be appreciated, while a single groove, pillar and actuator are shown, additional grooves, pillars and actuators may be circumferentially arranged in a spaced relationship around the lifting ring 1018 to bias the lifting ring 1018 in an upward direction.

In FIG. 17, the edge coupling ring 1014 is shown raised in an upward direction by the lifting ring 1018 using the pillar(s) 1060 and the actuator(s) 1064. The edge coupling ring 1014 can be removed from the processing chamber by a robot arm. More particularly, a robot arm 1102 is connected to the edge coupling ring 1014 by a holder 1104. The holder 1104 may include a self-centering feature 1110 that mates with the self-centering feature 1040 on the edge coupling ring 1014. As can be appreciated, the robot arm 1102 and the holder 1104 may bias the edge coupling ring upwardly to clear the self-centering feature 1048 on the lifting ring 1018. Then, the robot arm 1102, the holder 1104 and the edge coupling ring 1014 can be moved out of the processing chamber. The robot arm 1102, the holder 1104 and a new edge coupling ring can be returned and positioned on the lifting ring 1018. Then, the lifting ring 1018 is lowered. The opposite operation may be used to deliver a new edge coupling ring 1014 onto the lifting ring 1018.

Alternately, instead of lifting the robot arm 1102 and holder 1104 upwardly to lift the edge coupling ring 1014 off of the lifting ring 1018, the robot arm 1102 and holder 1104 can be positioned below and in contact with the raised edge coupling ring 1014. Then, the lifting ring 1018 is lowered and the edge coupling ring 1014 remains on the robot arm 1102 and holder 1104. The robot arm 1102, the holder 1104 and the edge coupling ring 1014 can be removed from the processing chamber. The opposite operation may be used to deliver a new edge coupling ring 1014 onto the lifting ring 1018.

Referring now to FIGS. 18-20, a movable edge coupling ring 1238 and a lifting ring 1018 are shown. In FIG. 18, one or more pillars 1210 are moved up and down by one or more actuators 1214 through bores 1220, 1224 and 1228 in the ESC baseplate 1032, the bottom edge coupling ring 1034 and the lifting ring 1018, respectively. In this example, a middle edge coupling ring 1240 or spacer is arranged between the movable edge coupling ring 1238 and the lifting ring 1018. The middle edge coupling ring 1240 may include self-centering features 1244 and 1246. A corresponding self-centering feature 1248 may be provided on the movable edge coupling ring 1238. The self-centering feature 1248 mates with the self-centering feature 1246 on the middle edge coupling ring 1240.

As is described in detail above, erosion of an upwardly facing surface of the movable edge coupling ring 1238 may occur during use. This, in turn, may alter the profile of the plasma. The movable edge coupling ring 1238 may be selectively moved in an upward direction using the pillars 1210 and the actuators 1214 to alter the profile of the plasma. In FIG. 19, the movable edge coupling ring 1238 of FIG. 18 is shown in a raised position. The middle edge coupling ring 1240 may remain stationary. Eventually, the movable edge coupling ring 1238 may be moved one or more times and then the edge coupling ring 1238 and the middle edge coupling ring 1240 may be replaced.

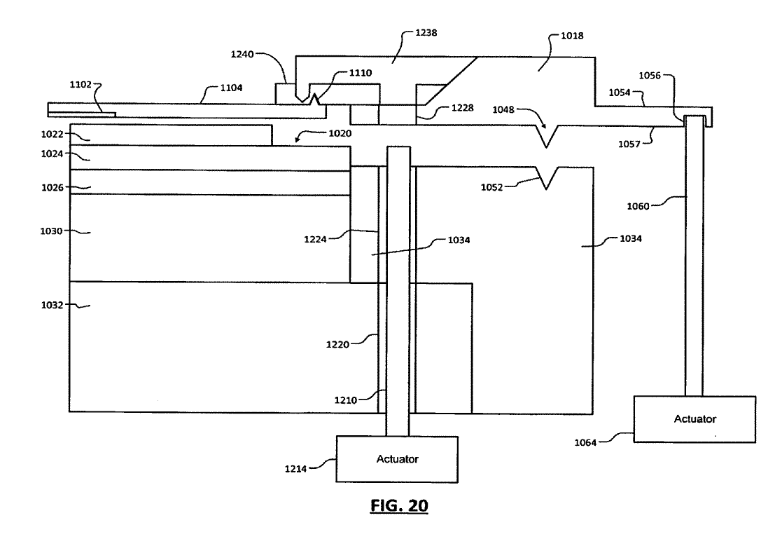

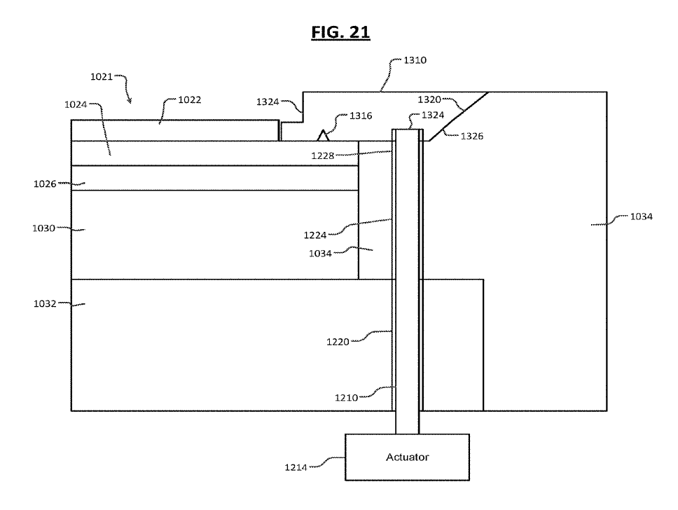

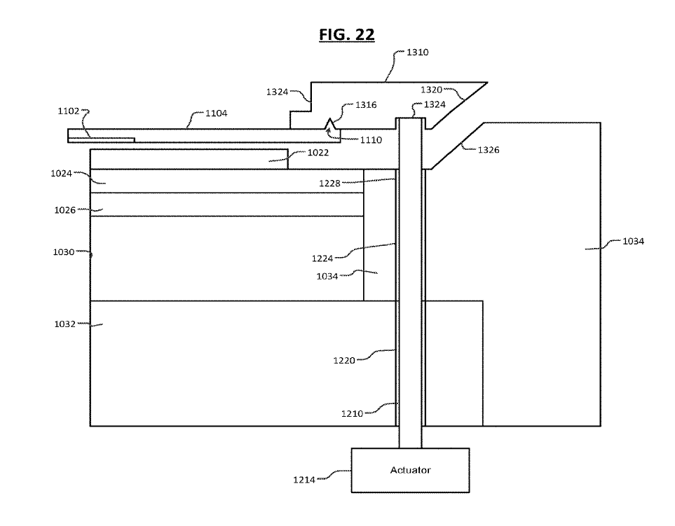

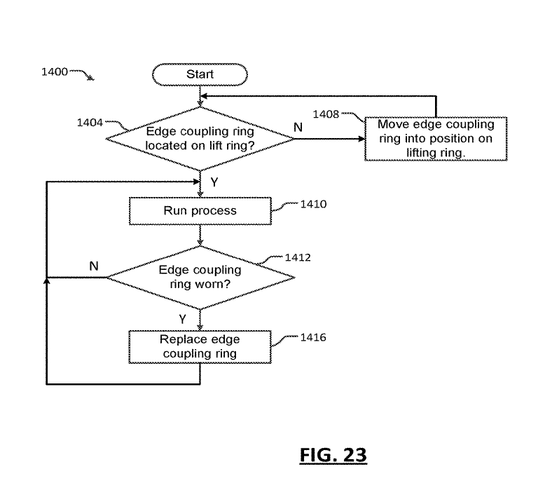

In FIG. 20, the actuator 1214 is returned to a lowered state and the actuator 1064 is moved to a raised state. The edge coupling ring 1238 and the middle edge coupling ring 1240 are lifted by the lifting ring 1018 and the movable edge coupling ring 1238 may be removed by the robot arm 1102 and the holder 1104.

As can be appreciated, the actuators can be arranged in the processing chamber or outside of the processing chamber. In some examples, the edge coupling rings may be supplied to the chamber via a cassette, loadlock, transfer chambers and the like. Alternatively, the edge coupling rings may be stored outside of the processing chamber but inside of the substrate processing tool.

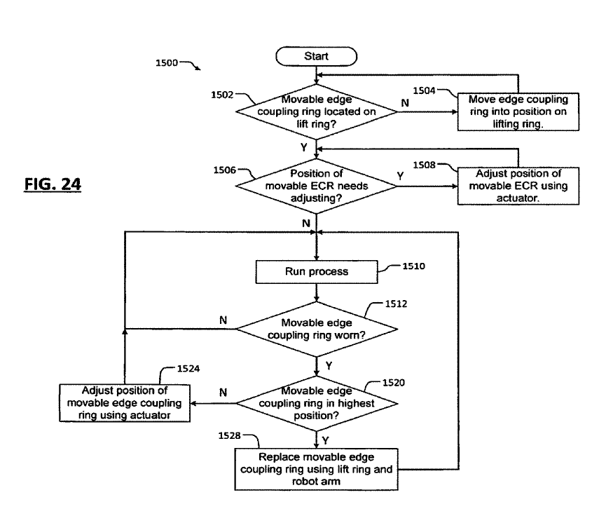

Referring now to FIGS. 21-22, the lifting ring can be omitted in some examples. An edge coupling ring 1310 is arranged on the bottom edge coupling ring 1034 and a radially outer edge of the pedestal. The edge coupling ring 1310 may include one or more self-centering features 1316 and 1320. The edge coupling ring 1310 may further include a groove 1324 for receiving a top surface of the pillar 1210, which is biased by the actuator 1214. The self-centering feature 1320 may be arranged against a corresponding self-centering feature 1326 of the bottom edge coupling ring 1034. In some examples, the self-centering features 1320 and 1326 are inclined planes.

In FIG. 22, the actuator 1214 and the pillar 1210 bias the edge coupling ring 1310 upwardly to remove the edge coupling ring 1310 or to adjust a plasma profile after erosion has occurred. The robot arm 1102 and the holder 1104 can be moved into position below the edge coupling ring 1310. The self-centering feature 1316 may be engaged by the self-centering feature 1110 on the holder 1104 connected to the robot arm 1102. Either the robot arm 1102 moves in an upward direction to provide clearance between the groove 1324 and the pillar 1210 or the pillar 1210 is moved downwardly by the actuator 1214 to provide clearance for the groove 1324.

Referring now to FIG. 23, a method 1400 for replacing an edge coupling ring without opening a processing chamber to atmospheric pressure is shown. At 1404, the method determines whether the edge coupling ring is located on the lifting ring. If 1404 is false, the method moves an edge coupling ring into position on the lifting ring using a robot arm at 1408. After the edge coupling ring is located on the lifting ring in the processing chamber, the process is run at 1408. At 1412, the method determines whether the edge coupling ring is worn using any of the criteria described above. If 1412 is false, the method returns to 1408 and the process may be run again. If the edge coupling ring is determined to be worn at 1412, the edge coupling ring is replaced at 1416 and the method continues at 1408.

Referring now to FIG. 24, a method 1500 adjusts a position of the movable edge coupling ring as needed to offset for erosion and selectively replaces the movable edge coupling ring when the movable edge coupling ring is determined to be worn. At 1502, the method determines whether a movable edge coupling ring is located on the lifting ring. If 1502 is false, an edge coupling ring is moved into position on the lifting ring at 1504 and the method continues at 1502.

If 1502 is true, the method determines whether a position of the movable edge coupling ring needs to be adjusted at 1506. If 1506 is true, the method adjusts a position of the movable edge coupling ring using an actuator and returns to 1506. When 1506 is false, the method runs the process at 1510. At 1512, the method determines whether the movable edge coupling ring is worn. If false, the method returns to 1510.

If 1512 is true, the method determines whether the movable edge coupling ring is in a highest (or fully adjusted) position at 1520. If 1520 is false, the method adjusts a position of the movable edge coupling ring using the actuator 1214 at 1524 and the method returns to 1510. If 1520 is true, the method replaces the movable edge coupling ring using the actuator 1064, the lifting ring 1018 and the robot arm 1102.

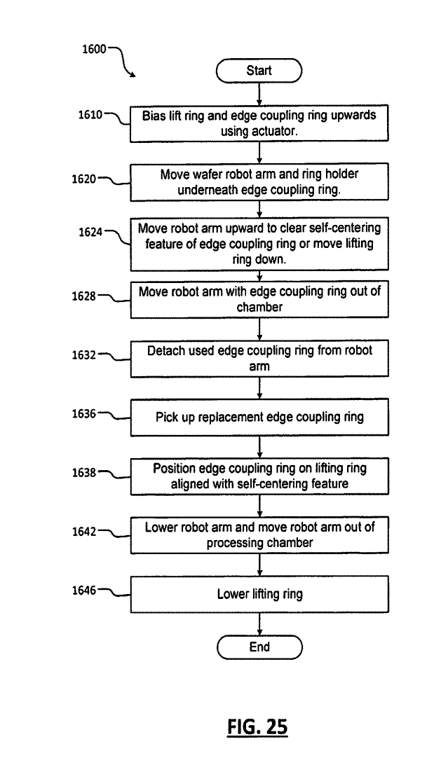

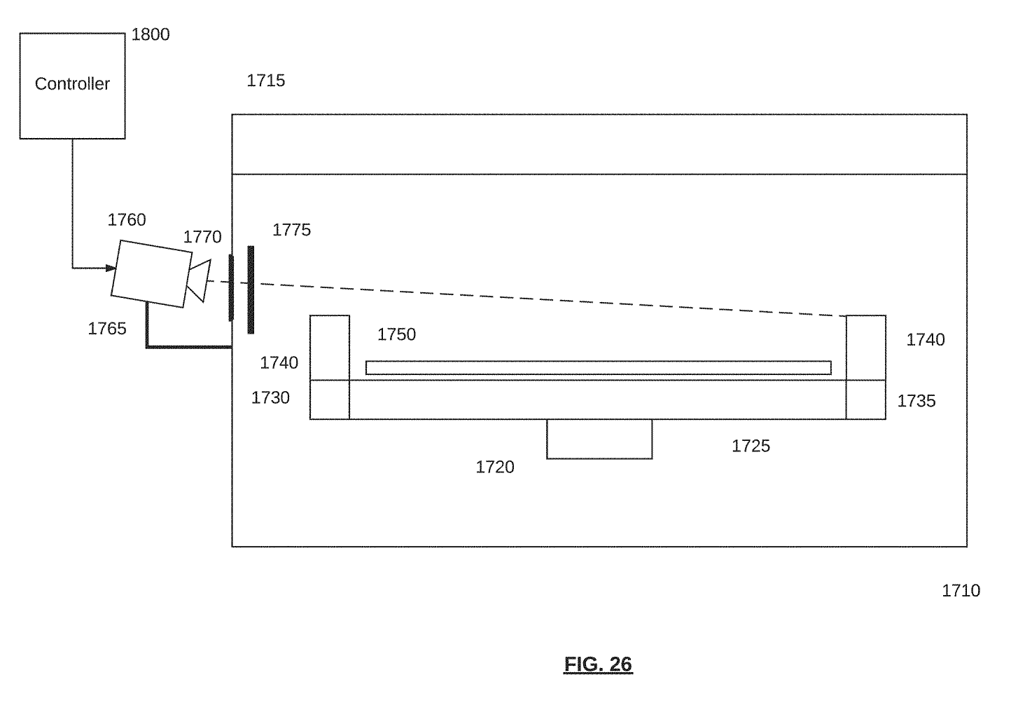

Referring now to FIG. 25, a method 1600 for replacing the edge coupling ring without opening the process chamber to atmospheric pressure is shown. At 1610, the lifting ring and edge coupling ring are biased upwardly using an actuator. At 1620, the robot arm and the holder are moved underneath the edge coupling ring. At 1624, the robot arm is moved upwardly to clear self-centering features of the edge coupling ring or the lifting ring is moved downwardly. At 1628, the robot arm with the edge coupling ring is moved out of the processing chamber. At 1632, the edge coupling ring is detached from the robot arm. At 1636, a replacement edge coupling ring is picked up by the robot arm. At 1638, the edge coupling ring is positioned on the lifting ring and aligned using one or more self-centering features. At 1642, the robot arm is lowered to allow sufficient clearance for the self-centering feature and the robot arm is removed from the chamber. At 1646, the lifting ring and the edge coupling ring are lowered into position.

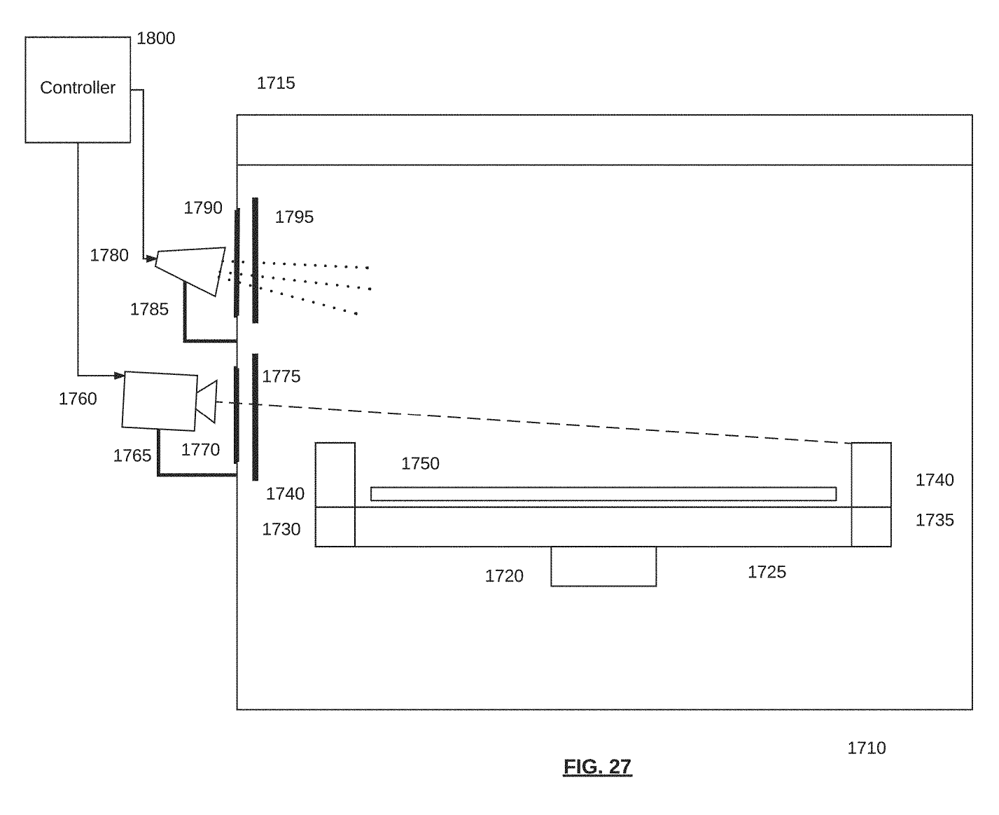

Referring now to FIG. 26, features of detection of edge coupling ring condition and position now will be described. This part of the description focuses on the detector and detection method according to features of the invention, enabling direct measurement of height and erosion of the edge coupling ring. Details of various elements of the processing chamber, including the ESC, the edge coupling ring, the controller, and the actuators, have been provided previously, and for the sake of brevity and clarity will not be repeated here.

In FIG. 26, a processing chamber 1710 has a window 1715 positioned over a top of the chamber. A pedestal 1720 in chamber 1710 has an electrostatic chuck (ESC) 1725 mounted thereon. Adjacent the ESC 1725 are actuator mechanisms 1730, 1735 which move an edge coupling ring 1740 horizontally and/or vertically, as described previously. Either or both of the actuator mechanisms 1730, 1735 may be installed as described with respect to preceding figures. A wafer 1750 is positioned on the ESC 1725 within edge coupling ring 1740.

A camera 1760 is mounted on attachment mechanism 1765 to view the edge coupling ring 1740 through a side view port 1770 in chamber 1710. The attachment mechanism 1765 may be a bracket, docking mechanism, or other suitable attachment mechanism enabling suitable vertical and/or horizontal movement of the camera 1760 relative to the side view port 1770, and enable appropriate focus of the camera 1760 on the appropriate portion of edge coupling ring 1740. In one feature, side view port 1770 includes a shutter 1775 to protect the material in the port during wafer processing. In one feature, the shutter 1775 operates using a pneumatic gate valve.

In one feature, as shown, the attachment mechanism 1765 mounts the camera 1760 on chamber 1710. In another feature, the attachment mechanism 1765 mounts the camera 1760 on structure next to the chamber 1710.

In some features, the controller (shown in previous figures) controls actuation, focus, and positioning of the camera 1760. In some features, a separate controller 1800 provides one or more of actuation, focus, and positioning for the camera. In some features, the camera itself provides its own focusing mechanism, but one of the controllers described herein supplements the camera's own focusing based on separate analysis of the images provided.

In other features, the camera 1760 is installed to permit viewing through window 1715. In FIG. 26, the camera 1760 is shown as focused on an inner edge of edge coupling ring 1740. The edge coupling ring 1740 is depicted in its new condition, at the time of installation in chamber 1710.

The camera 1760 is of sufficient resolution (e.g. number of pixels) to produce images of a suitable size to enable determination of the condition and position of the edge coupling ring 1740, and to provide direct measurement of ring height and ring erosion. In some features, the camera operates in macro (close up) mode, using a macro lens. In other features, the lens may be an optical zoom lens that provides appropriate magnification. Any combination of pixel number and magnification (macro, optical zoom or, in some features, digital zoom) that enables production of sufficient information (e.g. an image) to determine ring condition and position will be acceptable. In some features, the camera 1760 may operate using high dynamic range (HDR) imaging in combination with macro and/or zoom photography.

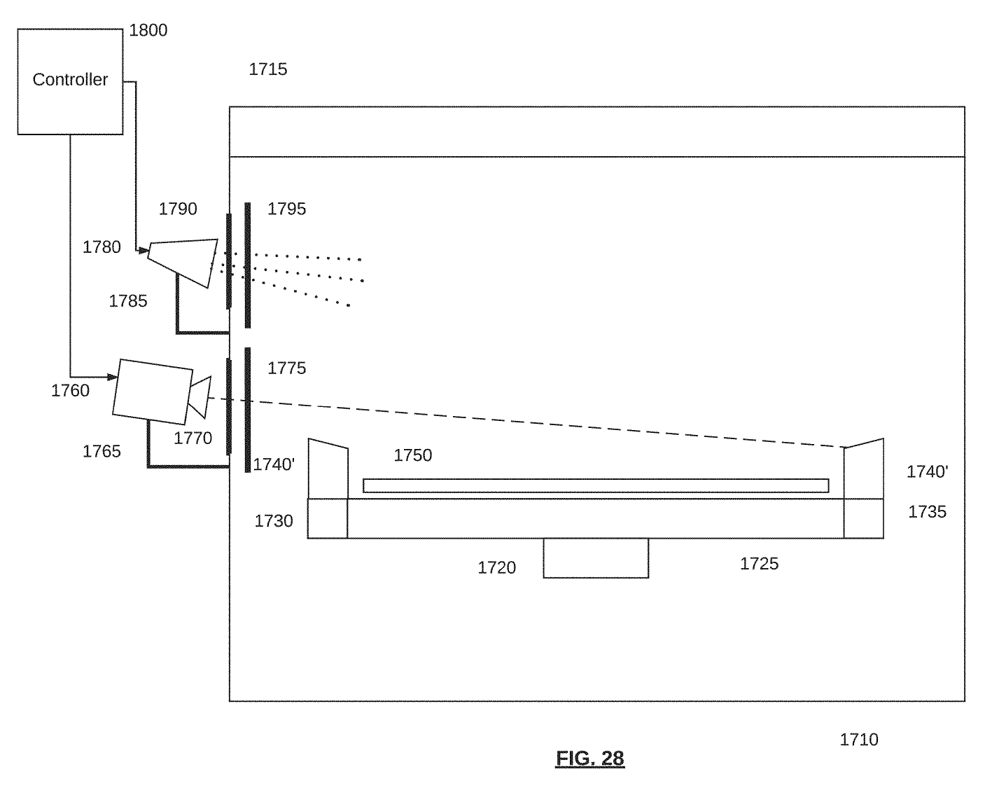

In one feature, in order for there to be sufficient light in chamber 1710 to illuminate the edge coupling ring 1740, plasma light is good enough. In other features, an external lighting source, such as a light emitting diode (LED) source, is provided. In FIG. 27, in addition to the elements depicted in FIG. 26, in some features an external lighting apparatus 1780 provides illumination within the chamber 1710. In one feature, as shown, the attachment mechanism 1785 mounts the lighting apparatus 1780 on chamber 1710. In another feature, the attachment mechanism 1785 mounts the lighting apparatus 1780 on structure next to the chamber 1710. In one feature, the lighting apparatus 1780 is attached to camera 1760. According to various features, that attachment is mechanical, or electrical, or both. In some features, an additional side view port 1790 is provided through which the lighting apparatus 1780 shines light into chamber 1710. The attachment mechanism 1785 may be a bracket, docking mechanism, or other suitable attachment mechanism enabling suitable vertical and/or horizontal movement of the camera 1760 relative to the side view port 1790. In some features, the additional side view port 1790 is on the same side of chamber 1710 as the side view port 1770. In other features, the additional side view port 1790 may be on a different side of chamber 1710 from the side view port 1770. In one feature, side view port 1790 includes a shutter 1795 to protect the material in the port during wafer processing. In one feature, the shutter 1795 operates using a pneumatic gate valve. In still other features, lighting apparatus 1780 shines light through the same side view port 1770 as camera 1760 uses, in which case no separate side view port 1790 is required.

For ease of illustrating the two side view ports 1770, 1790 separately, the chamber 1710 is depicted as being a little taller in FIG. 27 than in FIG. 26, but in some features the chamber is the same size in both Figures. If plasma light serves as the light source, the additional side view port 1790 is unnecessary.

In operation, the focus and/or position of camera 1760 can drift. In one feature, controller 1800 monitors the focus and position of camera 1760, and makes appropriate adjustments.

FIG. 28 has all of the same elements as FIG. 27, except that edge coupling ring 1740′ is shown as eroded, with the internal radius being shorter than the external radius. As described previously, this erosion or etching occurs as the wafer processing system processes more and more wafers. As also described previously, if the camera 1760 provides images showing that the edge coupling ring erodes too much to perform its function of controlling etching at the wafer's edge, the controller 560 controls one or both actuators 1730, 1735 to move the edge coupling ring 1740′ vertically as appropriate. In one feature, controllers 560 and 1800 communicate with each other so that controller 560 operates the appropriate actuator(s) in response to image data from controller 1800.

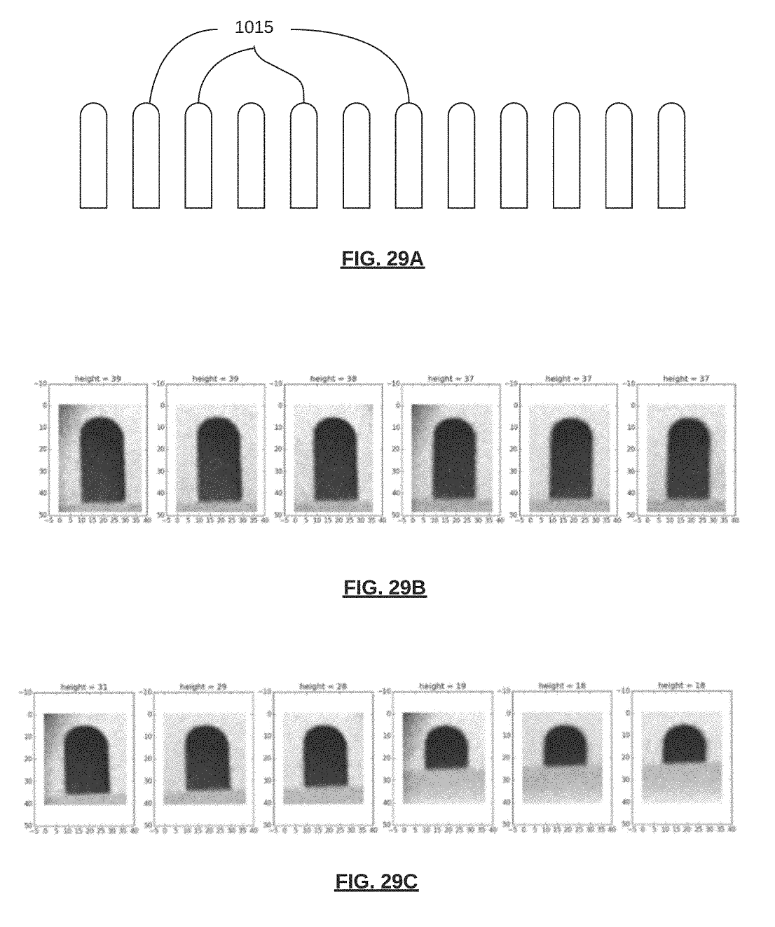

FIG. 29A is an enlarged view of openings 1015 in a liner 1012 shown in plan view in FIG. 15. The openings appear in a side view of the liner. The liner 1012 acts as a fixed reference on which the camera can focus to take images of the position and condition of the edge coupling ring.

FIGS. 29B and 29C show images of good and bad edge coupling ring placement respectively, relative to the openings 1015 in the liner 1012. In these Figures, the edge coupling ring is at the bottom of each image. The dark portions in each Figure are portions of the openings 1015. Consistency of height of the dark portions indicates the quality of placement. In one feature, the height of the dark portions is determined by counting the number of vertical dark pixels along a vertical axis at the center of the dark portions. In FIG. 29B, the relative equality of heights of the dark portions, and the size of those portions, indicate that edge coupling ring is placed properly. In FIG. 29C, the inconsistency of heights of the dark portions, and relatively short height of the dark portions on the right hand side of the Figure, indicate that the edge coupling ring is tilted.

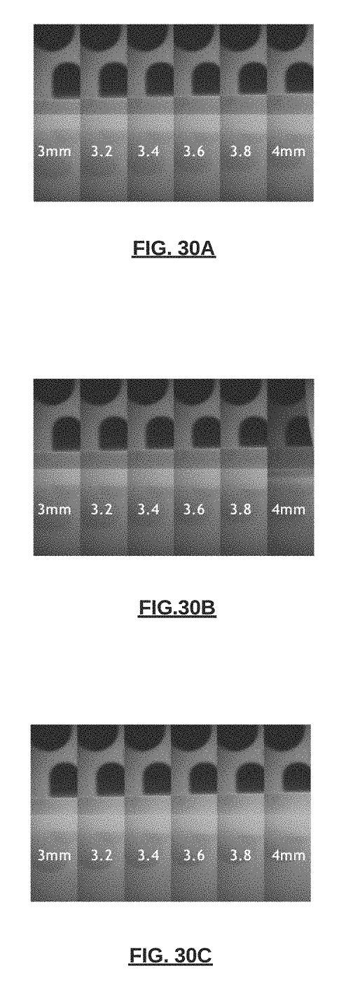

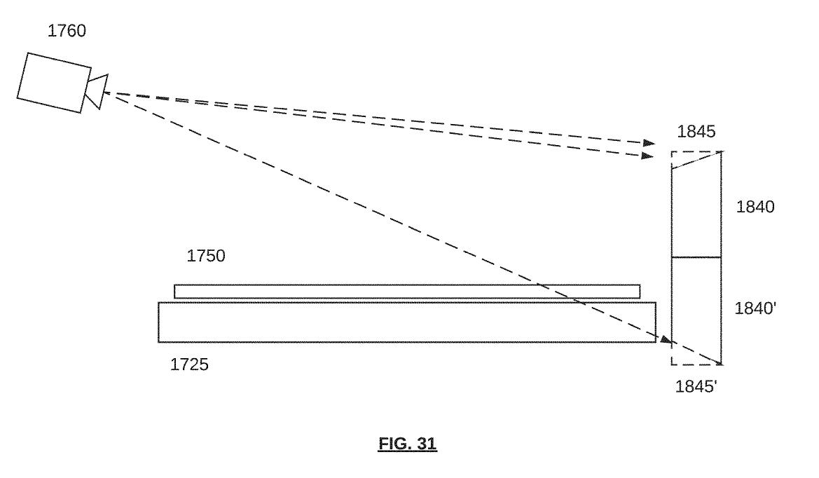

FIGS. 30A-C show raw images taken in the chamber, of various heights and conditions of the edge coupling ring 1740. FIG. 30A shows the condition of a new edge coupling ring, with heights at 3.0, 3.2, 3.4, 3.6, 3.8, and 4.0 mm as viewed in the six images placed side by side to form FIG. 30A. FIG. 30B shows the condition of a worn edge coupling ring, before recalibration and raising of the ring, at the same heights as in FIG. 30A. FIG. 30C shows the condition of a worn edge coupling ring, after recalibration and raising of the ring, at the same heights as in FIGS. 30A and 30B.

In one feature, raw images such as the ones shown in FIGS. 30A-30C may be used to calibrate the camera in the first instance, by looking at several different ring heights and ring conditions, again using the openings 1015 in the liner 1012 of FIG. 15 as a fixed reference. In one feature, calibration may be performed as follows. Initially, when a new edge coupling ring is installed, images may be taken at several different ring heights, for example, using one or more of the actuators to raise and lower the ring. Measuring the different heights of the ring, in pixels, and comparing those measurements to physical measurements, provides a gauge to enable calibration of a transition edge sensor (TES), and thereby calibrate the camera. Calibration can be useful to account for camera drift, whether in focus, or in focal length (degree of magnification). Drift in magnification, for example, can result in changed height measurement because of a change in relationship between number of pixels and number of μm.

FIG. 31 depicts an alternative way of directly measuring erosion of the edge coupling ring. In FIGS. 26-28, the camera 1760 is trained directly on the inside edge of the edge coupling ring. However, with this view, the camera can tend to provide an image of the entire top surface of the edge coupling ring, thereby potentially hiding or masking the actual amount of erosion. It becomes difficult to measure the height of the inner edge of the edge coupling ring because it is difficult to differentiate that edge from the rest of the upper surface of the ring. The image can appear blurry. It is desirable to view the front edge clearly, so as to measure its height (in number of pixels, translated to a unit of height such as μm), and thereby determine the degree of erosion.

To this end, in FIG. 31, instead of looking directly at the interior of the edge coupling ring, the camera 1760 can pick up a reflection of the interior of the edge coupling ring. The reflection can come from the surface of ESC 1725, or from the surface of wafer 1750. Either or both surfaces can have reflective qualities. Looking at the reflection, then, the camera 1760 picks up reflection 1840′ of edge coupling ring 1840. (The dotted lines show the eroded portion 1845 and its “reflection” 1845′.)

By looking at the reflection of the edge coupling ring instead of looking at the ring itself, the perspective problem is avoided. The height of the inside edge of the edge coupling ring can be measured directly to enable, in some instances, a clearer determination of the condition of the edge coupling ring.

There can be limits to detectability of ring erosion, even from looking at the reflection of the edge coupling ring. Because erosion occurs on the inside of the edge coupling ring, the erosion reduces the height of the inner edge of the ring relative to the outer edge. The greater the reduction, the greater the extent to which the upper surface of the ring is effectively tilted. At some point, the degree of “tilt” can be so great as to make it difficult to distinguish the inner edge of the ring in reflection, thereby making it difficult to measure the height of that inner edge, and hence to measure the extent of erosion. Inability to determine the extent of erosion can trigger either too rapid or too slow an adjustment of the ring height with the actuators, or even ring replacement. As a result, either the edge coupling ring will be replaced too soon, thereby wasting useful life of the ring, or the ring will be raised or replaced too late, leading to variability in etch profile near a radially outer edge of the wafer. In one feature, increasing the angle at which the camera 1760 views the reflected image, as erosion progresses, can compensate.

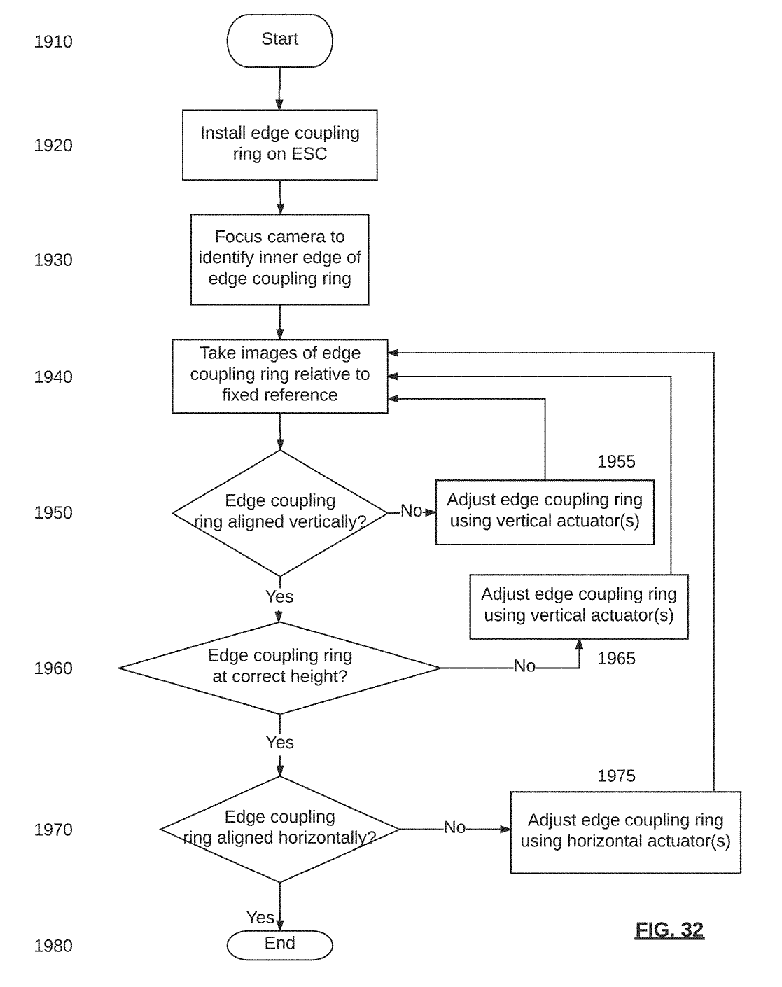

FIG. 32 depicts a method of seating an edge coupling ring using images from the camera. After the method begins at 1910, at 1920 the robot installs an edge coupling ring on the ESC. At 1930, the camera is focused to identify the inner edge of the ring. As discussed earlier, the camera can be focused either on the inner edge of the edge coupling ring, or on a reflection of the ring on either the ESC or the wafer.

At 1940, the camera takes images of the edge coupling ring relative to a fixed reference, such as the lifting ring of FIG. 15. At 1950, the images are processed and analyzed to determine whether there ring is aligned vertically, that is, whether there is any tilt in the edge coupling ring (for example, as shown in FIG. 29B). If there is tilt, then at 1955 the controller 560 controls one or more of the actuators to compensate for tilt, and the method returns to 1940 to obtain more images and check again (at 1950) whether there still is tilt.

If the edge coupling ring is not tilted, then at 1960 it is determined whether the edge coupling ring is at the correct height, again using the images that were obtained. If there is ring is not at the correct height, then at 1965 the controller 560 controls one or more of the vertical actuators to correct the height, and the method returns to 1940 to obtain more images and check again (at 1960) whether the edge coupling ring is at the correct height. In one feature, if tilt has already been adjusted, 1950 can be skipped, and the method can proceed directly from 1940 to 1960. In another feature, tilt and height can be measured and adjusted in a single step, by combining 1950 and 1960 into a single analysis, combining 1955 and 1965 into a single process, with the controller 560 controlling the vertical actuators in a single action.

Once the edge coupling is at the proper height and vertical alignment, then at 1970 it is determined whether the edge coupling ring is aligned horizontally on the ESC. If it is not aligned horizontally, then at 1975 the controller 560 causes one or more of the horizontal actuators to move the edge coupling ring, whereupon the method returns to 1940 to obtain more images and check again (at 1970) whether the edge coupling ring is aligned horizontally. In one feature, if vertical alignment has already been adjusted, then 1950 and 1960 can be skipped, and the method can proceed directly from 1940 to 1970.

In the method depicted in FIG. 32, vertical alignment and horizontal alignment need not be determined in the sequence indicated. The sequence can be reversed, so that horizontal alignment is adjusted first, followed by vertical alignment. In one feature, the controller 560 can receive all of the information regarding positioning of the edge coupling ring, and control multiple actuators at once to align the edge coupling ring. According to this feature, 1950, 1960, and 1970 can be combined into a single analysis, and 1955, 1965, and 1975 can be combined into one process.

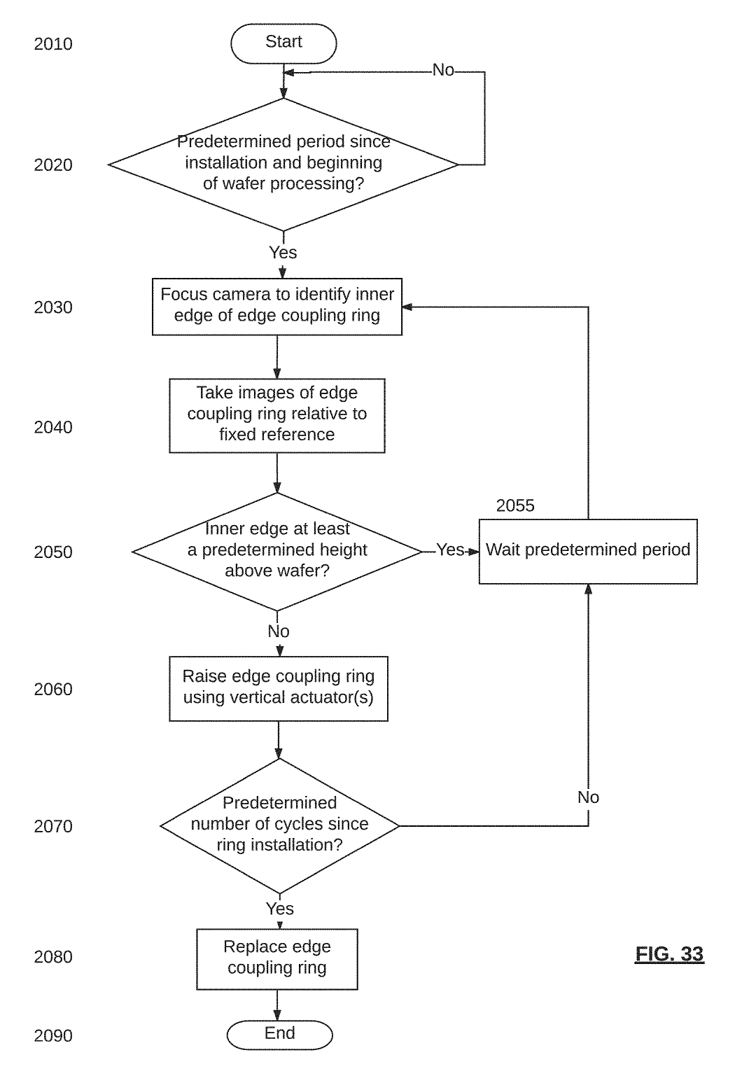

FIG. 33 depicts a method of adjusting an edge coupling ring using images from the camera. After the method begins at 2010, at 2020 it is determined whether a predetermined period has passed since the ring was installed and wafer processing began. If not, the method returns to 2020 to see if the predetermined period has passed.

In one feature, instead of waiting a predetermined period, at 2020 it is determined whether a predetermined number of processing cycles has occurred. If not, the method returns to 2020 to check the number of cycles again.

If either a predetermined period has passed or a predetermined number of processing cycles has occurred, at 2030 the camera is focused to identify the inner edge of the ring. As discussed earlier, the camera can be focused either on the inner edge of the edge coupling ring, or on a reflection of the ring on either the ESC or the wafer. At 2040, after focusing images are taken of the edge coupling ring relative to a fixed reference, and the height of the inner edge of the ring is measured. At 2050, if that inner edge is determined to be at least a predetermined height above the surface of the wafer, then at 2055 it is determined to wait a predetermined period. In one feature, instead of waiting a predetermined period, it is determined to wait for a predetermined number of wafer processing cycles. After either the predetermined period has passed or the predetermined number of cycles has occurred, the method returns to 2030, where the camera is refocused, and then to 2040, where more images are taken, and the determination at 2050 is repeated.

If the inner edge of the edge coupling ring is determined not to be at least a predetermined height above the surface of the wafer, at 2060 the controller 560 controls the vertical actuators to raise the edge coupling ring. At 2070, it is determined whether there has been a predetermined number of cycles since installation of the edge coupling ring. If not, the method returns to 2055 and waits a predetermined period. In one feature, at 2055 the method could wait a predetermined number of cycles.

If at 2070 it is determined that a predetermined number of cycles has passed, then at 2080 the edge coupling ring is replaced. In one feature, instead of seeing whether a predetermined number of cycles has passed, the amount of extension of the actuator could be measured. If the extension of the actuator exceeds a predetermined amount, then it could be determined that the edge coupling ring should be replaced. In another feature, instead of either of the immediately preceding alternatives, it could be determined whether a predetermined period of time has passed since installation of the edge coupling ring. If such a time period has passed, it could be determined that the edge coupling ring should be replaced.

After the edge coupling ring has been replaced, the method can end at 2090, or can return to start.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A OR B OR C), using a non-exclusive logical OR, and should not be construed to mean “at least one of A, at least one of B, and at least one of C.” It should be understood that one or more steps within a method may be executed in different order (or concurrently) without altering the principles of the present disclosure.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber having a first side view port;
a pedestal arranged in the processing chamber;
a liner surrounding the pedestal, the liner having at least one opening;
an edge coupling ring arranged adjacent to the pedestal, the edge coupling ring including a first portion located outside of and around a radially outer edge of a substrate when the substrate is placed on the pedestal;
an actuator configured to selectively move the first portion of the edge coupling ring relative to (i) the substrate and (ii) a second portion of the edge coupling ring located radially inward of the first portion to alter an edge coupling profile of the edge coupling ring, wherein the actuator is configured to move the first portion to at least one position where an upper surface of the first portion is above an upper surface of the substrate; and
a detector system configured to detect a condition of the edge coupling ring, the detector system comprising:
a camera configured to obtain image data of a plasma-facing surface of the edge coupling ring through the first view port; and
a first controller configured to receive the image data and determine at least one of a condition and a position of the plasma-facing surface of the edge coupling ring.

2. The substrate processing system of claim 1, wherein the detector system further comprises a lighting apparatus configured to provide light for the camera to obtain the image data of the edge coupling ring.

3. The substrate processing system of claim 2, wherein the lighting apparatus provides light through the first view port.

4. The substrate processing system of claim 2, wherein the processing chamber comprises a second view port, and wherein the lighting apparatus provides light through the second view port.

5. The substrate processing system of claim 1, further comprising:
a gas delivery system configured to deliver process gas and carrier gas to the processing chamber; and
a plasma generator configured to create plasma in the processing chamber to etch the substrate.

6. The substrate processing system of claim 5, wherein the plasma generator provides light for the camera to obtain the image data of the edge coupling ring.

7. The substrate processing system of claim 1, wherein the actuator moves the edge coupling ring vertically relative to the substrate in response to a condition indicating erosion of the plasma-facing surface of the edge coupling ring.

8. The substrate processing system of claim 1, wherein the actuator moves the edge coupling ring horizontally relative to the substrate in response to a condition indicating misalignment of the edge coupling ring.

9. The substrate processing system of claim 1, wherein the actuator moves the first portion of the edge coupling ring vertically relative to the substrate in response to a condition indicating misalignment of the edge coupling ring.

10. The substrate processing system of claim 1, further comprising a second controller configured to respond to the first controller to control the actuator to selectively move the first portion of the edge coupling ring.

11. The substrate processing system of claim 10, wherein the second controller is configured to effectuate replacement of the edge coupling ring in response to a determination of sufficient erosion of the edge coupling ring.

12. The substrate processing system of claim 1, wherein the camera is sighted onto the edge coupling ring to obtain the image data.

13. The substrate processing system of claim 1, further comprising an electrostatic chuck (ESC) arranged on the pedestal, wherein the camera is sighted onto at least one of the substrate and the ESC to obtain the image data.

14. The substrate processing system of claim 1, wherein the image data comprises image data of a section of the edge coupling ring relative to the at least one opening in the liner, and wherein the first controller calculates a height between the section of the edge coupling ring and a top of the at least one opening to determine at least one of a condition and a position of the edge coupling ring.

15. The substrate processing system of claim 14, wherein the liner has a plurality of openings; wherein the image data comprises image data of the section of the edge coupling ring relative to the plurality of openings in the liner, and wherein the first controller calculates a plurality of heights between the section of the edge coupling ring and corresponding tops of the plurality of openings, and wherein the first controller compares the plurality of heights to determine at least one of the condition and the position of the edge coupling ring.

16. The substrate processing system of claim 1, wherein the first controller adjusts a position of the camera in response to detection of a condition of the edge coupling ring.

17. In a substrate processing system comprising a processing chamber having a first side view port, a pedestal arranged in the processing chamber, a liner surrounding the pedestal, the liner having a plurality of openings, and an edge coupling ring arranged adjacent to the pedestal, the edge coupling ring including a first portion located outside of and around a radially outer edge of a substrate on the pedestal,
a detector system for detecting one or more of a condition and a position of the edge coupling ring, the detector system comprising:
a camera obtaining image data of the edge coupling ring through the first side view port; and
a controller receiving the image data and determining at least one of the position and the condition of a plasma-facing surface of the edge coupling ring;
wherein the image data comprises image data of a section of the edge coupling ring relative to the plurality of openings in the liner, and wherein the controller calculates a plurality of heights between the section of the edge coupling ring and different tops of the plurality of openings, and wherein the controller compares the plurality of heights to determine one of the condition and the position of the edge coupling ring.

18. The detector system of claim 17, wherein the substrate processing system further comprises an electrostatic chuck (ESC) arranged on the pedestal, and wherein the camera is sighted onto one of the substrate and the ESC to obtain the image data.

19. A method for determining at least one of a condition and a position of an edge coupling ring in a substrate processing system, the method comprising:
identifying an inner edge of the edge coupling ring;
obtaining image data of the edge coupling ring relative to a fixed reference;
processing the image data to determine whether the edge coupling ring is aligned vertically;
in response to a determination that the edge coupling ring is not aligned vertically, adjusting the edge coupling ring vertically;
determining whether the inner edge of the edge coupling ring is at a predetermined height;
in response to a determination that the inner edge of the edge coupling ring is not at the predetermined height, determining whether the edge coupling ring can be adjusted vertically; and
in response to a determination that the edge coupling ring can be adjusted vertically, adjusting the edge coupling ring vertically.

20. The method of claim 19, further comprising:
in response to a determination that the edge coupling ring cannot be adjusted vertically, instructing replacement of the edge coupling ring.

21. The method of claim 19, wherein determining whether the edge coupling ring can be adjusted vertically comprises determining whether there has been a predetermined number of semiconductor processing cycles since installation of the edge coupling ring in the substrate processing system.

22. The method of claim 19, wherein determining whether the edge coupling ring can be adjusted vertically comprises determining whether a predetermined amount of time has elapsed since installation of the edge coupling ring in the semiconductor processing system.

23. The method of claim 19, wherein determining whether the edge coupling ring can be adjusted vertically comprises determining whether the edge coupling ring has been raised vertically to its maximum extent.

24. The method of claim 19, wherein adjusting the edge coupling ring vertically comprises adjusting one portion of the edge coupling ring vertically relative to another portion of the edge coupling ring.

25. The method of claim 19, further comprising:
determining whether the edge coupling ring is aligned horizontally; and
in response to a determination that the edge coupling ring is not aligned horizontally, adjusting the edge coupling ring horizontally.

26. The method of claim 25, wherein adjusting the edge coupling ring horizontally comprises moving the edge coupling ring relative to a pedestal in the substrate processing system, the substrate being arranged on the pedestal.
